(19) United States
(12) Patent Application Publication
(10) Pub. No.: US 2016/0050770 A1
(43) Pub. Date: Feb. 18, 2016

(54) BONDING APPARATUS AND METHOD OF FABRICATING DISPLAY DEVICE USING THE SAME

(71) Applicant: Samsung Display Co., Ltd., Yongin-city (KR)

(72) Inventors: Hyeon Deuk HWANG, Cheonan-si (KR); Chul Ho JUNG, Daegu (KR)

(21) Appl. No.: 14/611,962

(22) Filed: Feb. 2, 2015

(30) Foreign Application Priority Data
Aug. 12, 2014 (KR) 10-2014-0104375

(51) Int. Cl. H05K 3/46; H05K 5/00; H05K 3/00

(52) U.S. Cl. CPC H05K 3/46; H05K 3/0091; H05K 5/0017

(57) ABSTRACT

A method of fabricating a display device includes placing a first anisotropic conductive film on a display panel; aligning a first electronic device on the first anisotropic conductive film; performing a pre-compression process on the first electronic device using a first pressure unit; placing a second anisotropic conductive film on the display panel; aligning a second electronic device on the second anisotropic conductive film; performing a pre-compression process on the second electronic device using a second pressure unit separated from the first pressure unit; and simultaneously performing a first main compression process on the first electronic device at a first temperature using the first pressure unit and a second main compression process on the second electronic device at a second temperature different from the first temperature using the second pressure unit. The second thermal compression process is performed by maintaining the second temperature using a first temperature control unit.

### CROSS REFERENCE TO RELATED APPLICATION

This application claims priority from and the benefit of Korean Patent Application No. 10-2014-0104375 filed on Aug. 12, 2014, which is hereby incorporated by reference for all purposes as if fully set forth herein.

### BACKGROUND

1. Field

The following description relates to a bonding apparatus and a method of fabricating a display device using the same.

2. Discussion of the Background

Of display devices, organic light-emitting display devices, which are self-luminous display devices, are drawing attention as next-generation display devices due to their wide viewing angle, high contrast, and fast response time.

An organic light-emitting display device includes a display panel, which displays an image using an organic light-emitting device, and a driving circuit unit, a driver chip, which transmits signals to the driving circuit unit, and a flexible circuit board, which transmits signals to the driver chip.

Generally, the driver chip and the flexible circuit board are electrically connected to a pad area of the display panel by an anisotropic conductive film having conductive balls. That is, as an insulator of each of the conductive balls of the anisotropic conductive film disposed between the driver chip and the pad area of the display panel, and between the flexible circuit board and the pad area of the display panel, is broken by e.g., a thermal compression process, the driver circuit chip and the flexible circuit board are electrically connected to the pad area of the display panel. Each of the conductive balls of the anisotropic conductive film is covered with a thin insulator before the thermal compression process.

A compression temperature of a first thermal compression process, which breaks an insulator of each conductive ball between the driver chip and the pad area of the display panel is different from a compression temperature of a second thermal compression process, which breaks an insulator of each conductive ball between the flexible circuit board and the pad area of the display panel. Therefore, if the first thermal compression process and the second thermal compression process are performed separately, for example, if the second thermal compression process is performed after the first thermal compression process, heat generated in the second thermal compression process may cause an anisotropic conductive film attached between the driver chip and the pad area of the display panel to be lifted by the first thermal compression process. In this case, the reliability of electrical connection between the pad area of the display panel and the driver chip can be reduced.

On the contrary, if the first thermal compression process is performed after the second thermal compression process, heat generated in the first thermal compression process may cause an anisotropic conductive film attached between the flexible circuit board and the pad area of the display panel from being lifted by the second thermal compression process. This can reduce the reliability of electrical connection between the pad area of the display panel and the flexible circuit board.

### SUMMARY

Exemplary embodiments of the present invention provide a bonding apparatus, which can improve the reliability of electrical connection between each of a driver chip, a flexible circuit board, and a pad area of a display panel via an anisotropic conductive film.

Exemplary embodiments of the present invention provide a method of fabricating a display device using a bonding apparatus, which can improve the reliability of electrical connection between each of a driver chip, a flexible circuit board, and a pad area of a display panel via an anisotropic conductive film.

Additional aspects will be set forth in the detailed description which follows, and, in part, will be apparent from the disclosure, or may be learned by practice of the inventive concept.

Exemplary embodiments of the present invention provide a bonding apparatus including: a stage to support a display panel, a first electronic device, and a second electronic device disposed thereon; and a bonding head configured to thermally compress the first electronic device and the second electronic device onto the display panel to bond the first electronic device and the second electronic device to the display panel, in which the bonding head includes: a first pressure unit configured to thermally compresses the first electronic device at a first temperature; and a second pressure unit, which is separated from the first pressure unit, configured to thermally compresses the second electronic device at a second temperature different from the first temperature.

Exemplary embodiments of the present invention provide a method of fabricating a display device including: disposing a first anisotropic conductive film on a display panel; aligning a first electronic device on the first anisotropic conductive film; disposing a second anisotropic conductive film on the display panel; aligning a second electronic device on the second anisotropic conductive film; performing a first thermal compression on the first electronic device; and performing a second thermal compression on the second electronic device, in which the first thermal compression process and the second thermal compression process are simultaneously performed.

Exemplary embodiments of the present invention provide a method of fabricating a display device, the method including: placing a first anisotropic conductive film on a display panel; aligning a first electronic device on the first anisotropic conductive film; performing a pre-compression process on the first electronic device using a first pressure unit; placing a second anisotropic conductive film on the display panel; aligning a second electronic device on the second anisotropic conductive film; performing a pre-compression process on the second electronic device using a second pressure unit separated from the first pressure unit; and simultaneously performing a first main compression process on the first electronic device at a first temperature using the first pressure unit, and a second main compression process on the second electronic device at a second temperature different from the first temperature using the second pressure unit.

It is to be understood that both the foregoing general description and the following detailed description are exemplary and explanatory and are intended to provide further explanation of the invention as claimed. Other features and aspects will be apparent from the following detailed description, the drawings, and the claims.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the principles of the invention.

FIG. 1 is a cross-sectional view of a bonding apparatus according to an exemplary embodiment of the present invention.

FIGS. 2 through 4 are cross-sectional views illustrating a method of fabricating a display using the bonding apparatus of FIG. 1 according to exemplary embodiments of the present invention.

FIGS. 5 and 6 are perspective and cross-sectional views of a display device fabricated using the method of FIGS. 2 through 4.

FIG. 7 is a cross-sectional view of a bonding apparatus according to an exemplary embodiment of the present invention.

FIG. 8 is an enlarged cross-sectional view of a second pressure unit illustrated in FIG. 7.

FIG. 9 is a graph illustrating the temperatures of a first pressure unit and the second pressure unit of FIG. 7 according to an exemplary embodiment of the present invention.

FIGS. 10 through 12 are cross-sectional views illustrating a method of fabricating a display device using the bonding apparatus of FIG. 7 according to exemplary embodiments of the present invention.

FIG. 13 is a cross-sectional view of a bonding apparatus according to an exemplary embodiment of the present invention.

FIG. 14 is an enlarged cross-sectional view of a first pressure unit illustrated in FIG. 13.

FIGS. 15 through 17 are cross-sectional views illustrating a method of fabricating a display device using the bonding apparatus of FIG. 13 according to exemplary embodiments of the present invention.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements. It will be understood that for the purposes of this disclosure, “at least one of X, Y, and Z” can be construed as X only, Y only, Z only, or any combination of two or more items X, Y, and Z (e.g., XYZ, XZ, XYY, YZ, ZZ). Throughout the drawings and the detailed description, unless otherwise described, the same drawing reference numerals are understood to refer to the same elements, features, and structures. The relative size and depiction of these elements may be exaggerated for clarity.

It will also be understood that when a layer is referred to as being “on” another layer or substrate, it can be directly on the other layer or substrate, or intervening layers may also be present. The same reference numbers indicate the same components throughout the specification.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Hereinafter, exemplary embodiments of the present invention will be described with reference to the attached drawings.

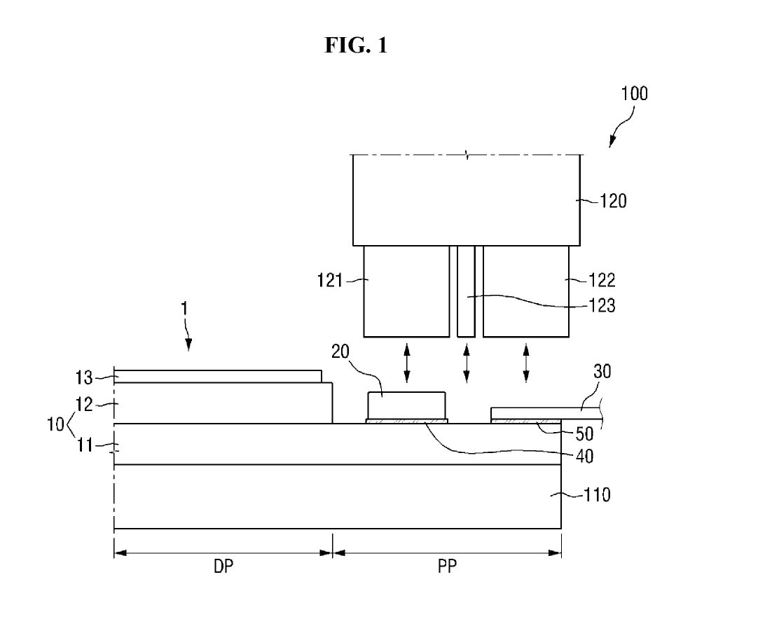

FIG. 1 is a cross-sectional view of a bonding apparatus according to an exemplary embodiment of the present invention.

Referring to FIG. 1, the bonding apparatus 100 includes a stage 110 and a bonding head 120. The bonding apparatus 100 may be used to bond a first electronic device 20 and a second electronic device 30 to a display panel 10 by, for example, thermal compression.

The stage 110 may support the display panel 10 when the first electronic device 20 and the second electronic device 30 are bonded to a pad area PP of the display panel 10 by thermal compression.

The display panel 10 may be a panel of a display device 1 (such as an organic light-emitting display device, a liquid crystal display (LCD) device, etc.), which may display an image. The display panel 10 may include a first display substrate 11 having a display area DP and the pad area PP, a second display substrate 12 coupled to the first display substrate 11, and a polarizer 13 formed on the second display substrate 12 to prevent or reduce reflection of external light. A plurality of signal lines, which may include scan lines and data lines, and a plurality of pixels may be located in the display area DP of the first display substrate 11, and a plurality of metal wirings connected to the signal lines may be located in the pad area PP.

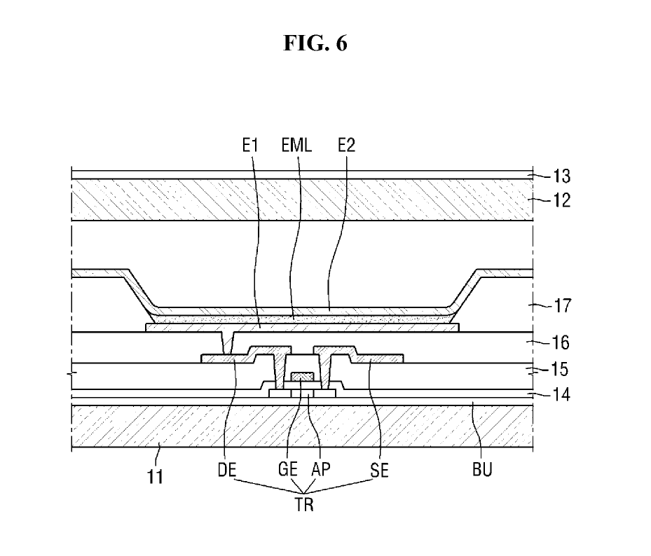

When the display panel 10 is a display panel of an organic light-emitting display device, the display panel may include an organic light-emitting device, which may include a light-emitting layer, such as a light-emitting layer EML of FIG. 6, formed between the first display substrate 11 and the second display substrate 12.

The first electronic device 20 may be a driver chip mounted on the metal wirings of the pad area PP of the first display substrate 11 using a chip-on-glass (COG) method. The driver chip may be an integrated circuit (IC) chip and may include any one of a scan driver and a data driver. The scan driver may supply scan signals to the pixels via the scan lines, and the data driver may supply data signals to the pixels via the data lines.

The second electronic device 30 may be a flexible circuit board. The second electronic device 30 may be mounted on the metal wirings of the pad area PP of the first display substrate 11 using, for example, a film-on-glass (FOG) method. The flexible circuit board may deliver an external control signal to the first electronic device 20 so that the first electronic device 20 can generate a scan signal and a data signal.

The bonding head 120 is placed above the stage 110 and may bond the first electronic device 20 and the second electronic device 30 onto the display panel 10. More specifically, the boding head 120 may bond the first electronic device 20 and the second electronic device 30 onto the metal wirings of the pad area PP of the first display substrate 11 by thermally compressing the first electronic device 20 and the second electronic device 30. The bonding head 120 includes a first pressure unit 121, a second pressure unit 122, and a heat dissipation unit 123 (or a first temperature control unit), which can move vertically.

The first pressure unit 121 is placed above the first electronic device 20. The first pressure unit 121 may be configured to apply heat and/or pressure to the first electronic device 20. Accordingly, the first pressure unit 121 may bond the first electronic device 20 onto the metal wirings of the pad area PP of the first display substrate 11 by thermally compressing the first electronic device 20 onto the pad area PP of the first display substrate 11.

More specifically, the first pressure unit 121 may move vertically toward the stage 110 to bond the first electronic device 20 onto the metal wirings of the pad area PP of the first display substrate 11 by performing a pre-compression process on the first electronic device 20 and performing a first main compression process on the first electronic device 20. The pre-compression process may be performed with a pre-compression pressure and a pre-compression temperature during a pre-compression time. The first main compression process may be performed with a first main compression pressure and a first main compression temperature (or a first temperature) during a first main compression time. The bonding of the first electronic device 20 and the metal wirings of the pad area PP of the first display substrate 11 may be achieved by a first anisotropic conductive film 40, which may include conductive balls and/or adhesive resin.

One or more of the conductive balls of the first anisotropic conductive film 40 may be covered with a thin insulator before the first main compression process on the first electronic device 20. However, the thin insulator may be broken during or after the first main compression process on the first electronic device 20. Accordingly, the first electronic device 20 may be electrically connected to the metal wirings of the pad area PP of the first display substrate 11 by the one or more conductive balls, which may have broken insulator(s). The adhesive resin of the first anisotropic conductive film 40 may fix the first electronic device 20 to the metal wirings of the pad area PP of the first display substrate 11 during or after the first main compression process on the first electronic device 20.

In an example, the pre-compression time may be, approximately 1 second, the pre-compression pressure may be, approximately 1 megapascal (MPa), and/or the pre-compression temperature may be, approximately 80 degrees Celsius (° C.). However, aspects of the invention are not limited thereto, such that the pre-compression time, the pre-compression pressure, and the pre-compression temperature may vary according to the type of the first anisotropic conductive film 40 and/or the type of the first electronic device 20. In addition, in an example, the first main compression time may be, approximately 5 seconds, the first main compression pressure may be, approximately 130 MPa, and/or the first main compression temperature may be, approximately 220° C. However, aspects of the invention are not limited thereto, such that the first main compression time, the first main compression pressure, and the first main compression temperature may vary according to the type of the first anisotropic conductive film 40 and the type of the first electronic device 20.

The second pressure unit 122 is placed above the second electronic device 30, which may be thermally compressed with a second main compression temperature (or a second temperature) different from the first main compression temperature of the first electronic device 20. More specifically, the second pressure unit 122 may be configured and/or moved to apply heat and/or pressure to the second electronic device 30. Accordingly, the second pressure unit 122 may bond the second electronic device 30 onto the metal wirings of the pad area PP of the first display substrate 11 by thermally compressing the second electronic device 30 onto the pad area PP of the first display substrate 11.

More specifically, the second pressure unit 122 may move in a vertical direction toward the stage 110 and may bond the second electronic device 30 onto the metal wirings of the pad area PP of the first display substrate 11 by performing a pre-compression process on the second electronic device 30 and performing a second main compression process on the second electronic device 30. The pre-compression process may be performed with a pre-compression pressure and a pre-compression temperature during a pre-compression time. The second main compression process may be performed with a second main compression pressure and a second main compression temperature (or a second temperature) during a second main compression time. The bonding of the second electronic device 30 and the metal wirings of the pad area PP of the first display substrate 11 may be achieved by a second anisotropic conductive film 50, which may includes conductive balls and/or adhesive resin.

One or more of the conductive balls of the second anisotropic conductive film 50 may be covered with a thin insulator before the second main compression process on the second electronic device 30. However, the thin insulator may be broken during or after the second main compression process on the second electronic device 30. Accordingly, the second electronic device 30 may be electrically connected to the metal wirings of the pad area PP of the first display substrate 11 by the conductive balls, one or more of the conductive balls having the broken insulator. The adhesive resin of the second anisotropic conductive film 50 may fix the second electronic device 30 to the metal wirings of the pad area PP of the first display substrate 11 during or after the second main compression process on the second electronic device 30.

The pre-compression process on the second electronic device 30 may be performed independently of the pre-compression process on the first electronic device 20. The pre-compression time, pre-compression pressure and pre-compression temperature of the second electronic device 30 may be equal to those of the first electronic device 20.

At least one of the second main compression time, the second main compression pressure, and the second main compression temperature may vary according to at least one of the type of the second anisotropic conductive film 50 and the type of the second electronic device 30.

The second main compression process on the second electronic device 30 may be performed at the same time as the first main compression process on the first electronic device 20. In this case, the second main compression time of the second electronic device 30 may be equal to the first main compression time of the first electronic device 20.

The second main compression pressure and second main compression temperature of the second electronic device 30 may be different from the first main compression pressure and first main compression temperature of the first electronic device 20. For example, the second main compression pressure and second main compression temperature of the second electronic device 30 may be smaller than the first main compression pressure and first main compression temperature of the first electronic device 20. In an example, the second main compression pressure of the second electronic device 30 may be approximately 3 MPa, and the second main compression temperature of the second electronic device 30 may be approximately 180° C. In this case, the first electronic device 20 may be a driver chip that can withstand high temperatures, and the first anisotropic conductive film 40 may have a high density of conductive balls. Unlike the first electronic device 20, the second electronic device 30 may be a flexible circuit board that cannot withstand high temperatures. Unlike the first anisotropic conductive film 40, the second anisotropic conductive film 50 may have a low density of conductive balls.

The heat dissipation unit 123 is disposed between the first pressure unit 121 and the second pressure unit 122. The first pressure unit 121 and the second pressure unit 122 may move vertically toward the stage 110 and contact a top surface of the first electronic device 20 and a top surface of the second electronic device 30 to simultaneously perform the first main compression process and the second main compression process. Further, when the first pressure unit 121 and the second pressure unit 122 may move vertically toward the stage 110 to perform the compressions processes, the heat dissipation unit 123 may also move vertically together with the first pressure unit 121 and the second pressure unit 122 to contact a top surface of the pad area PP of the first display substrate 11. Accordingly, the heat dissipation unit 123 can reduce or prevent heat transfer between the first pressure unit 121 and the second pressure unit 122 when the first main compression process of the first pressure unit 121 and the second main compression process of the second pressure unit 122 are performed simultaneously.

The heat dissipation unit 123 can reduce an unwanted change in the first main compression temperature of the first pressure unit 121 or the second main compression temperature of the second pressure unit 122 due to the heat transfer between the first pressure unit 121 and the second pressure unit 122. In addition, the heat dissipation unit 123 can prevent or limit the first anisotropic conductive film 40 fixed or disposed between the first electronic device 20 and the metal wirings of the pad area PP of the first display substrate 11, or the second anisotropic conductive film 50 fixed or disposed between the first electronic device 30 and the metal wirings of the pad area PP of the first display substrate 11, from being lifted or moved due, at least in part to the heat transfer between the first pressure unit 121 and the second pressure unit 122.

The heat dissipation unit 123 may be made of a heat dissipation material that can prevent or reduce heat transfer. For example, such heat dissipation material may be made of, without limitation, at least one of a silica-based material, an aerogel-based material, a polyurethane-based material, a polyisocyanurate-based material, a phenol-based material, a urea-based material, a polystyrene-based material, a fiberglass-based material, an icynene-based material, a cotton-based material, a wool-based material, a cellulose-based material, a polyethylene-based material, a vermiculite-based material, and glass. In addition, the heat dissipation unit 123 may include the heat dissipation material and/or a latent heat material. The latent heat material may be a wax-based material, such as hydrocarbon or an alkane mixture, or an inorganic material, such as salt hydrate.

The bonding apparatus 100 includes the heat dissipation unit 123 disposed between the first pressure unit 121 and the second pressure unit 122. Further, heat transfer between the first pressure unit 121 and the second pressure unit 122 may be prevented or reduced when the first main compression process of thermally compressing the first electronic device 20 using the first pressure unit 121 and the second main compression process of thermally compressing the second electronic device 30 using the second pressure unit 122 are performed simultaneously.

According to aspects of the invention, the bonding apparatus 100 can reduce an unwanted change in the first main compression temperature of the first pressure unit 121 or the second main compression temperature of the second pressure unit 122. In addition, the bonding apparatus 100 may prevent or limit the lifting of the first anisotropic conductive film 40, which may contact the first electronic device 20, or the second anisotropic conductive film 50, which contacts the second electronic device 30, thereby improving the reliability of electrical connection between the first electronic device 20 and the pad area PP of the first display substrate 11 by the first anisotropic conductive film 40 and the reliability of electrical connection between the second electronic device 30 and the pad area PP of the first display substrate 11 by the second anisotropic conductive film 50.

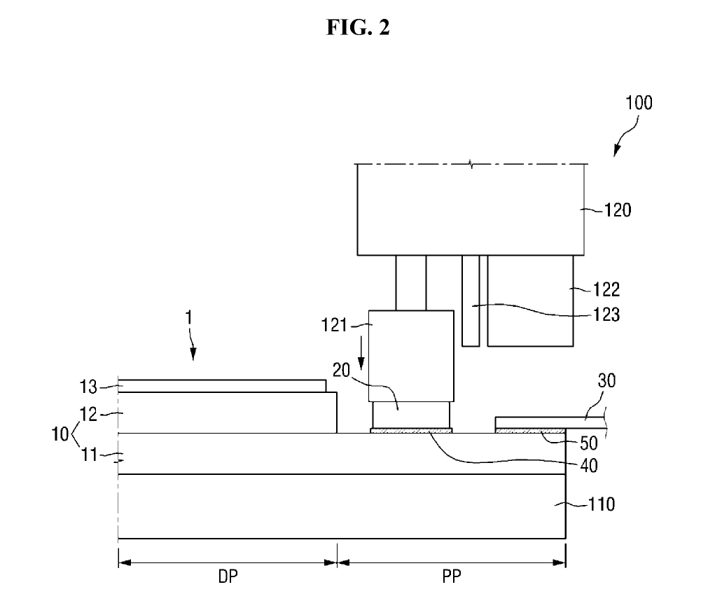

FIGS. 2 through 4 are cross-sectional views illustrating a method of fabricating a display device using the bonding apparatus of FIG. 1.

Referring to FIG. 2, a first anisotropic conductive film 40 is placed on metal wirings of a pad area PP of a first substrate 11 of a display panel 10 placed on the stage 110. A first electronic device 20 may be aligned on the first anisotropic conductive film 40, and the first pressure unit 121 of the bonding head 120 may be moved vertically toward the stage 110 to perform a pre-compression process on the first electronic device 20. The pre-compression process may be performed with a pre-compression pressure and/or a pre-compression temperature during a pre-compression time. The pre-compression pressure of the first pressure unit 121 and/or heat of the pre-compression temperature of the first pressure unit 121 may be transmitted to the first anisotropic conductive film 40 via the first electronic device 20.

The pre-compression process on the first electronic device 20 may be performed with a pressure of approximately 1 MPa and a temperature of approximately 80° C. for approximately 1 second. After the pre-compression process on the first electronic device 20, the first pressure unit 121 may be moved vertically to be separated from the first electronic device 20. Although not illustrated in the drawings, the vertical movement of the first pressure unit 121 may be driven by a driving apparatus connected to the first pressure unit 121, the pre-compression pressure of the first pressure unit 121 may be provided by a compression apparatus connected to the first pressure unit 121, and the pre-compression temperature of the first pressure unit 121 may be controlled by a heater connected to or embedded in the first pressure unit 121.

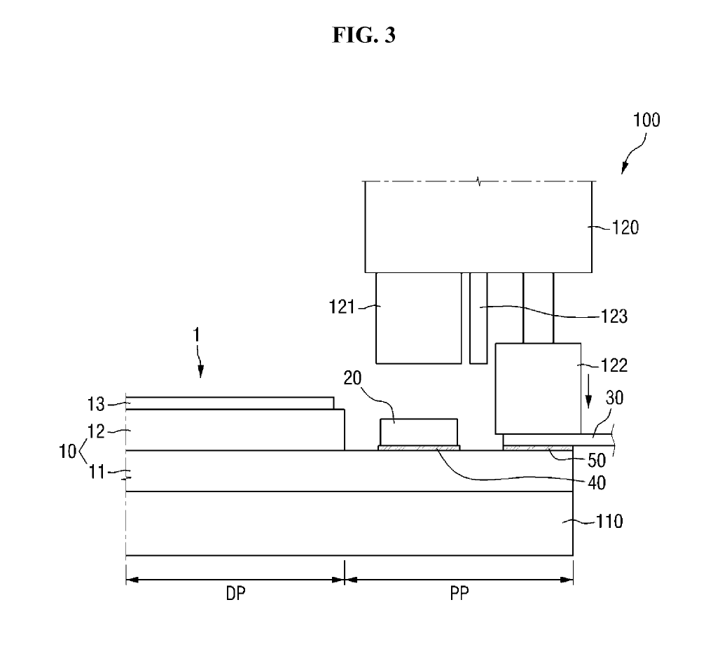

Referring to FIG. 3, a second anisotropic conductive film 50 may be placed on the metal wirings of the pad area PP of the first substrate 11 of the display panel 10. A second electronic device 30 may be aligned on the second anisotropic conductive film 50, and the second pressure unit 122 of the bonding head 120 may be moved vertically toward the stage 110 to perform a pre-compression process on the second electronic device 30. The pre-compression process may be performed with a pre-compression pressure and a pre-compression temperature during a pre-compression time. The pre-compression pressure of the second pressure unit 122 and heat of the pre-compression temperature of the second pressure unit 122 may be transmitted to the second anisotropic conductive film 50 via the second electronic device 30.

The pre-compression process on the second electronic device 30 may be performed with a pressure of approximately 1 MPa and a temperature of approximately 80 r for approximately 1 second. After the pre-compression process on the second electronic device 30, the second pressure unit 122 may be moved vertically to be separated from the second electronic device 30. Although not illustrated in the drawings, the vertical movement of the second pressure unit 122 may be driven by a driving apparatus connected to the second pressure unit 122, the pre-compression pressure of the second pressure unit 122 may be provided by a compression apparatus connected to the second pressure unit 122, and the pre-compression temperature of the second pressure unit 122 may be controlled by a heater connected to or embedded in the second pressure unit 122.

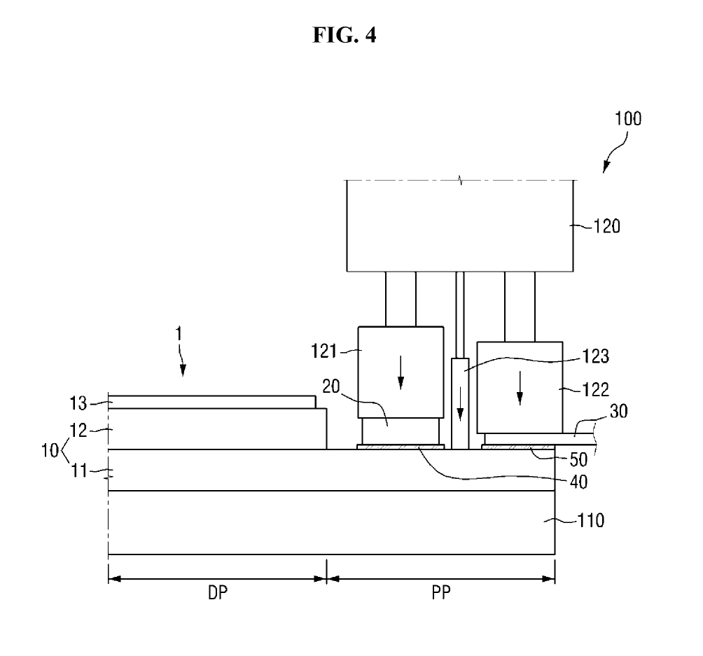

Referring to FIG. 4, the first pressure unit 121, the second pressure unit 122 and the heat dissipation unit 123 of the bonding head 120 are vertically moved toward the stage 110, such that the heat dissipation unit 123 is located on the pad area PP of the first display substrate 11 between the first pressure unit 121 and the second pressure unit 122. In this state, the first pressure unit 121 may perform a first main compression process on the first electronic device 20 with a first main compression pressure and/or a first main compression temperature. Further, at the same time, the second pressure unit 122 may perform a second main compression process on the second electronic device 30 with a second main compression pressure and/or a second main compression temperature. The first compression pressure and/or heat of the first compression temperature may be transmitted to the first anisotropic conductive film 40 via the first electronic device 20. Further, at the same time, the second compression pressure and heat of the second compression temperature may be transmitted to the second anisotropic conductive film 50 via the second electronic device 30. In this case, an insulator of one or more conductive balls of the first anisotropic conductive film 40 may be broken, and the first electronic device 20 may be electrically connected to the metal wirings of the pad area PP of the first display substrate 11 by the conductive balls. In addition, the first electronic device 20 may be fixed or disposed onto the metal wirings of the pad area PP of the first display substrate 11 by adhesive resin or the like. At the same time, an insulator of one or more conductive balls of the second anisotropic conductive film 50 may be broken, and the second electronic device 30 may be electrically connected to the metal wirings of the pad area PP of the first display substrate 11 by the conductive balls. In addition, the second electronic device 30 may be fixed or disposed onto the metal wirings of the pad area PP of the first display substrate 11 by adhesive resin or the like.

In an example, the first compression process on the first electronic device 20 may be performed with a pressure of approximately 130 MPa and/or a temperature of approximately 220° C. for approximately 5 seconds. The second compression process on the second electronic device 30 may be performed with a pressure of approximately 3 MPa and/or a temperature of approximately 180° C. for approximately 5 seconds.

After the first main compression process on the first electronic device 20 and the second main compression process on the second electronic device 30, the first pressure unit 121 and the second pressure unit 122 may be moved vertically to be separated from the first electronic device 20 and the second electronic device 30. The heat dissipation unit 123 may also be moved in the same direction, more specifically, vertically, together with the first pressure unit 12 and the second pressure unit 122.

A display device fabricated using the bonding apparatus 100 will now be described in more detail using an organic light-emitting display device as an example.

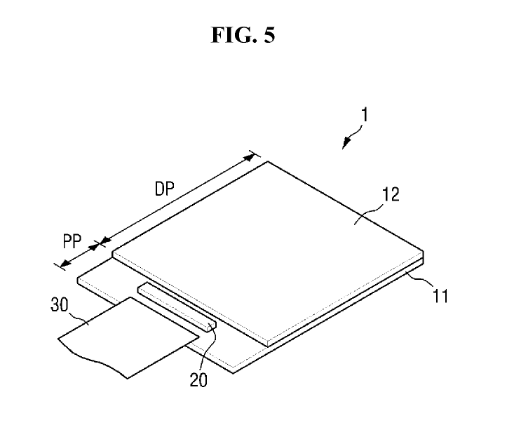

FIGS. 5 and 6 are perspective and cross-sectional views of a display device fabricated using the method of FIGS. 2 through 4.

Referring to FIG. 5, the display device 1 has a basic structure in which an organic light-emitting device (including the light-emitting layer EML of FIG. 6) is disposed between a first display substrate 11, which includes a display area DP having a plurality of pixels and a pad area PP, and a second display substrate 12. In addition, the display device 1 may include a polarizer 13 disposed on the first display substrate 11 to prevent or reduce reflection of external light. The display device 1 may include a first electronic device 20 (e.g., a driver chip) and a second electronic device 30 (e.g., a flexible circuit board) mounted on the pad area PP of the first display substrate 11.

Referring to FIG. 6, each pixel of the display device 1 includes the first display substrate 11, a buffer layer BU, a semiconductor layer AP, a gate electrode GE, a source electrode SE, a drain electrode DE, a gate insulating layer 14, an interlayer insulating film 15, a planarization layer 16, a pixel defining layer 17, a first electrode E1, the light-emitting layer EML, a second electrode E2, the second display substrate 12, and the polarizer 13.

The first display substrate 11 may be made of a transparent insulating material. For example, the first display substrate 11 may be made of glass, quartz, ceramic, plastic, etc. The first display substrate 11 may be shaped like a flat plate. According to exemplary embodiments, the first display substrate 11 may be made of a material that can be easily bent by an external force. The first display substrate 11 may support other components disposed thereon.

The buffer layer BU may be disposed on the first display substrate 11. The buffer layer BU may prevent or reduce penetration of impurity elements and planarize a top surface of the first display substrate 11. The buffer layer BU may be made of any one of a silicon nitride (SiNₓ) layer, a silicon oxide (SiO₂) layer, and a silicon oxynitride (SiOₓN_{y}) layer. According to exemplary embodiments, the buffer layer BU may be omitted.

The semiconductor layer AP may be disposed on the first display substrate 11, more specifically, on the buffer layer BU. The semiconductor layer AP may be made of an amorphous silicon layer or a polycrystalline silicon layer. The semiconductor layer AP may include a channel region undoped with impurities and p+-doped source and drain regions, which may be disposed on both sides of the channel region, to contact the source and drain electrodes SE and DE, respectively. Impurities used to dope the semiconductor layer AP may be P-type impurities, such as boron (B). For example, B₂H₆ may be used as the impurities. The type of impurities used to dope the semiconductor layer AP may vary.

The gate insulating layer 14 may be disposed on the semiconductor layer AP. The gate insulating layer 14 may insulate the gate electrode GE and the semiconductor layer AP from each other. The gate insulating layer 14 may be made of silicon nitride (SiNₓ) or silicon oxide (SiO₂).

The gate electrode GE may be disposed on the gate insulating layer 14. The gate electrode GE may be placed to overlap at least a region of the semiconductor layer AP. A voltage applied to the gate electrode GE may determine whether the semiconductor layer AP may be configured to be conductive or non-conductive. For example, a relatively high voltage applied to the gate electrode GE may cause the semiconductor layer AP to become conductive, electrically connecting the drain electrode DE and the source electrode SE to each other. A relatively low voltage applied to the gate electrode GE may cause the semiconductor layer AP to become non-conductive, insulating the drain electrode DE and the source electrode SE from each other.

The interlayer insulating film 15 may be disposed on the gate electrode GE. The interlayer insulating film 15 may cover the gate electrode GE to insulate the gate electrode GE from the source electrode SE and the drain electrode DE. The interlayer insulating film 15 may be made of silicon nitride (SiNₓ) or silicon oxide (SiO₂).

The source electrode SE and the drain electrode DE may be disposed on the interlayer insulating film 15. The source electrode SE and the drain electrode DE may respectively be connected to the semiconductor layer AP by through holes, which may penetrate through the interlayer insulating film 15 and the gate insulating layer 14.

The source electrode SE, the drain electrode DE, the gate electrode GE and the semiconductor layer AP may form a thin-film transistor TR. The thin-film transistor TR may determine whether to deliver a signal, which may be transmitted to the source electrode SE, to the drain electrode DE according to a voltage applied to the gate electrode GE.

The planarization layer 16 may be disposed on the interlayer insulating film 15, the source electrode SE and the drain electrode DE. The planarization layer 16 may form a flat surface by removing a step formed on the top surface of one or more of the source electrode SE and the drain electrode DE to increase the emission efficiency of the light-emitting layer EML, which may be disposed on the planarization layer 16.

The planarization layer 16 may be made of one or more materials selected from the group consisting of polyacrylates resin, epoxy resin, phenolic resin, polyamides resin, polyimides resin, unsaturated polyesters resin, polyphenylene ethers resin, polyphenylene sulfides resin, and benzocyclobutene (BCB).

A via hole may be formed in the planarization layer 16. The first electrode E1 may contact and be electrically connected to the drain electrode DE by the via hole.

The first electrode E1 may be disposed on the planarization layer 16 and under the light-emitting layer EML. The first electrode E1 may be electrically connected to the drain electrode DE by the via hole to deliver a signal transmitted to the drain electrode DE to the light-emitting layer EML.

The first electrode E1 may be made of a reflective conductive material, a transparent conductive material, or a semi-transparent conductive material. Examples of the reflective conductive material include lithium (Li), calcium (Ca), lithium fluoride/calcium (LiF/Ca), lithium fluoride/aluminum (LiF/Al), aluminum (Al), silver (Ag), magnesium (Mg), and gold (Au). Examples of the transparent conductive material include indium tin oxide (ITO), indium zinc oxide (IZO), zinc oxide (ZnO), and indium oxide (In₂O₃). The semi-transparent conductive material may be a co-deposition material containing one or more of Mg and Ag or may be one or more of Mg, Ag, Ca, Li, and Al.

The pixel defining layer 17 may be disposed on the planarization layer 16. The pixel defining layer 17 may define each of the pixels included in the organic light-emitting display device 1. The pixel defining layer 17 may cover not the entire top surface of the planarization layer 16. An opening may be formed in a region of the pixel defining layer 17, which may not cover the top surface of the planarization layer 16. A top surface of the first electrode E1 may be exposed through the opening of the pixel defining layer 17. An organic light-emitting element including the light-emitting layer EML may be disposed on the first electrode E1 in the opening. Although not illustrated in the drawing, the organic light-emitting element may include, without limitation, at least one of a hole injection layer, a hole transport layer, an electron transport layer, and an electron injection layer.

The light-emitting layer EML is formed on the first electrode E1. The light-emitting layer EML may emit light by recombining holes supplied from the first electrode E1 and electrons supplied from the second electrode E2. More specifically, holes and electrons provided to the light-emitting layer EML may combine together to form excitons. When the excitons change from an excited state to a ground state, the light-emitting layer EML may emit light. The light-emitting layer EML may include a red light-emitting layer which emits red light, a green light-emitting layer which emits green light, and a blue light-emitting layer which emits blue light.

The second electrode E2 may be disposed on the light-emitting layer EML. The second electrode E2 may be made of the same material as the first electrode E1, but aspects of the invention are not limited thereto. According to exemplary embodiments of the present invention, the second electrode E2 may be a common electrode disposed in the pixels of the display device 1. Further, the second electrode E2 may be disposed on the light-emitting layer EML and the entire top surface of the pixel defining layer 17. The light emission of the light-emitting layer EML may be controlled by an electric current flowing between the first electrode E1 and the second electrode E2.

The second display substrate 12 may be made of a transparent insulating material. For example, the second display substrate 12 may be made of glass, quartz, ceramic, plastic, etc. The second display substrate 12 may be shaped like a flat plate. According to exemplary embodiments, the second display substrate 12 may be made of a material that can be easily bent by an external force.

The polarizer 13 is disposed on the second display substrate 12 and may prevent or reduce reflection of external light.

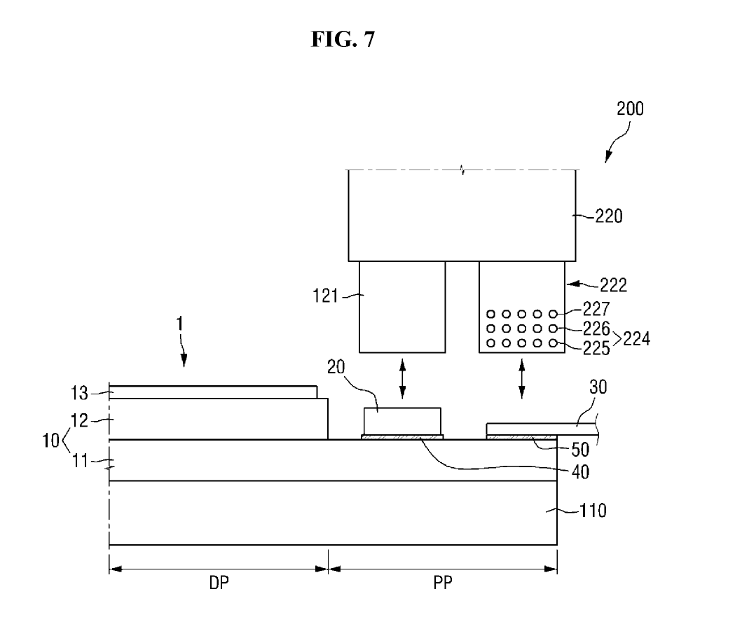

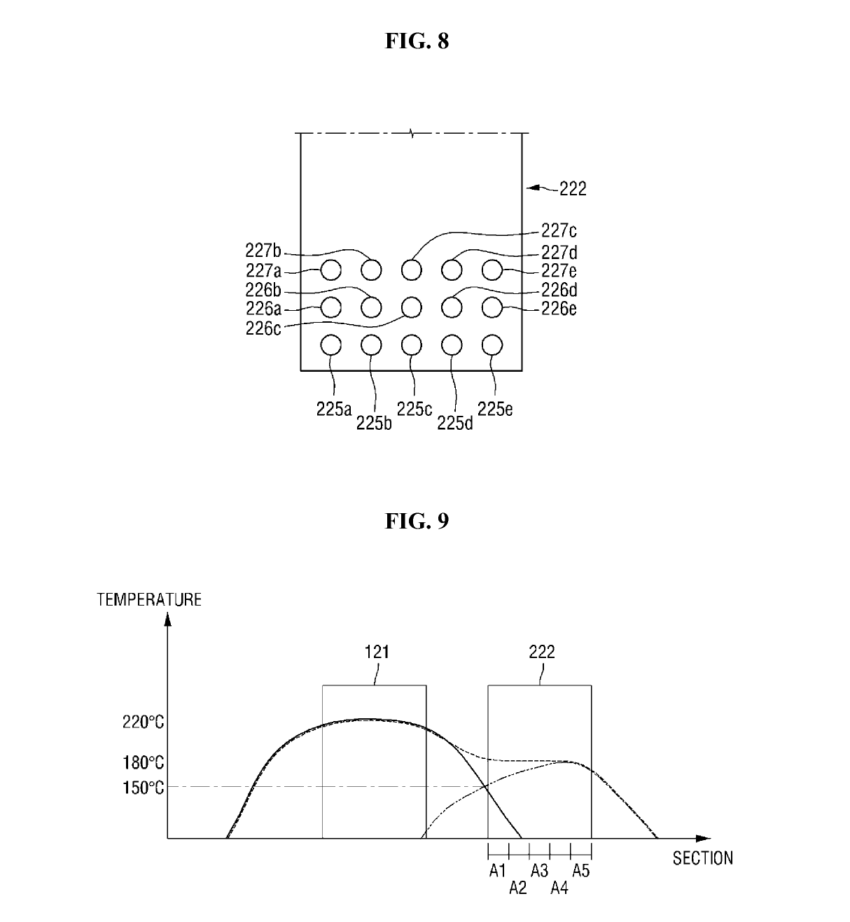

FIG. 7 is a cross-sectional view of a bonding apparatus according to an exemplary embodiment of the present invention. FIG. 8 is an enlarged cross-sectional view of a second pressure unit illustrated in FIG. 7. FIG. 9 is a graph illustrating the temperatures of a first pressure unit and the second pressure unit of FIG. 7.

Referring to FIG. 7, the bonding apparatus 200 may have the same configuration as the bonding apparatus 100 of FIG. 1, except the second pressure unit 222 and omission of the heat dissipation unit 123. The second pressure unit 222 of the bonding apparatus 200 will mainly be described below.

Referring to FIGS. 7 and 8, the bonding apparatus 200 includes a stage 110 and a bonding head 220.

The bonding head 220 is placed above the stage 110 and may bond a first electronic device 20 and a second electronic device 30 onto a display panel 10. More specifically, the first electronic device 20 and the second electronic device 30 may be bonded onto metal wirings of a pad area PP of a first display substrate 11 by substantially thermally compressing the first electronic device 20 and the second electronic device 30 onto the pad area PP of a first display substrate 11. The bonding head 220 includes the first pressure unit 121 and the second pressure unit 222, which can move vertically.

The second pressure unit 222 may be similar to the second pressure unit 122 of FIG. 1. However, the second pressure unit 222 includes a first temperature control unit 224 and a first temperature sensor 227.

The first temperature control unit 224 includes a plurality of hot wires 225. Heat may be transmitted, to the plurality of hot wires 225, from a heat source (e.g., a heater) and a plurality of cooling pipes 226, through which coolant flows. The first temperature control unit 224 may control the temperature in each region of the second pressure unit 222. The hot wires 225 may include a first hot wire 225a, a second hot wire 225b, a third hot wire 225c, a fourth hot wire 225d, and a fifth hot wire 225e, which may be arranged sequentially in order of smallest to largest distance from the first pressure unit 121. The cooling pipes 226 may cool the hot wires 225 and may include a first cooling pipe 226a, a second cooling pipe 226b, a third cooling pipe 226c, a fourth cooling pipe 226d, and a fifth cooling pipe 226e, which may correspond to the first hot wire 225a, the second hot wire 225b, the third hot wire 225c, the fourth hot wire 225d, and the fifth hot wire 225e, respectively.

The first temperature control unit 224 may provide heat to the second pressure unit 222 through the hot wires 225, such that the second pressure unit 222 can have a pre-compression temperature when performing a pre-compression process on the second electronic device 30 after moving vertically toward the stage 110. The first hot wire 225a, the second hot wire 225b, the third hot wire 225c, the fourth hot wire 225d and the fifth hot wire 225e may equally provide heat of the pre-compression temperature to the second pressure unit 222.

When the temperature of a partial region of the second pressure unit 222, for example, a region in which the third hot wire 225c is located, is higher than the pre-compression temperature, the region in which the third hot wire 225c is located is cooled using the third cooling pipe 226c to adjust the temperature of the region in which the third hot wire 225c is located to the pre-compression temperature. The pre-compression temperature may be, for example, approximately 80° C.

In addition, the first temperature control unit 224 may provide heat to the second pressure unit 222 through the hot wires 225, such that the second pressure unit 222 can have a second main compression temperature when performing a second main compression process on the second electronic device 30 after moving vertically toward the stage 110. The first hot wire 225a, the second hot wire 225b, the third hot wire 225c, the fourth hot wire 225d, and the fifth hot wire 225e may provide the second pressure unit 222 with heat having a temperature lower than the second main compression temperature. Even if the heat of the first pressure unit 121 is transferred to the second pressure unit 222, the temperature of the second pressure unit 222 can be prevented or impeded from becoming higher than the second main compression temperature. The second main compression temperature may be, for example, approximately 180° C.

The first hot wire 225a, the second hot wire 225b, the third hot wire 225c, the fourth hot wire 225d and the fifth hot wire 225e may provide heat of different temperatures to the second pressure unit 222. More specifically, thermal temperatures of the first hot wire 225a, the second hot wire 225b, the third hot wire 225c, the fourth hot wire 225d and the fifth hot wire 225e may be controlled, such that the temperature of the second pressure unit 222 may increase as the distance from the first pressure unit 121 increases. This may be because the temperature of a region of the second pressure unit 222, which may be close to the first pressure unit 121, is significantly increased by heat transferred from the first pressure unit 121 and/or because the temperature of a region of the second pressure unit 222, which may be far away from the first pressure unit 121, is not significantly increased by the heat transferred from the first pressure unit 121.

For example, if the second main compression temperature is 180° C., the first hot wire 225a, the second hot wire 225b, the third hot wire 225c, the fourth hot wire 225d, and the fifth hot wire 225e may respectively provide heat of 150° C., heat of 155° C., heat of 160° C., heat of 165° C., and heat of 170° C. to the second pressure unit 222. As illustrated in FIG. 9, the second pre-compression temperature (indicated by a dotted line) may be maintained at approximately 180° C. in A1, A2, A3, A4 and A5 sections of the second pressure unit 222. In FIG. 9, a solid line may represent a first main compression temperature of the first pressure unit 121, chain lines may represent temperatures of heat provided to the second pressure unit 222 through the first hot wire 225a, the second hot wire 225b, the third hot wire 225c, the fourth hot wire 225d and the fifth hot wire 225e, and the dotted line may represent the second main compression temperature of the second pressure unit 222 after the first main compression temperature of the first pressure unit 121 is transferred to the second pressure unit 222. In FIG. 9, the A1 section, the A2 section, the A3 section, the A4 section and the A5 section respectively are regions of the second pressure unit 222 in which the first hot wire 225a, the second hot wire 225b, the third hot wire 225c, the fourth hot wire 225d and the fifth hot wire 225e may be located.

The first temperature sensor 227 may be installed at a position corresponding to the first temperature control unit 224. The first temperature sensor 227 may include an equal number of sensor units to the number of the hot wires 225 at positions corresponding to the hot wires 225, respectively. The sensor units include a first sensor unit 227a, a second sensor unit 227b, a third sensor unit 227c, a fourth sensor unit 227d, and a fifth sensor unit 227e.

The first sensor unit 227a, the second sensor unit 227b, the third sensor unit 227c, the fourth sensor unit 227d, and the fifth sensor unit 227e may respectively sense temperatures of the regions of the second pressure unit 222 in which the first hot wire 225a, the second hot wire 225b, the third hot wire 225c, the fourth hot wire 225d and the fifth hot wire 225e may be located. Further, the first sensor unit 227a, the second sensor unit 227b, the third sensor unit 227c, the fourth sensor unit 227d, and the fifth sensor unit 227e may provide temperature information to a control unit (not illustrated), which may control the overall operation of the bonding apparatus 200. Accordingly, the control unit may maintain the temperatures of the regions of the second pressure unit 222 in which the first hot wire 225a, the second hot wire 225b, the third hot wire 225c, the fourth hot wire 225d and the fifth hot wire 225e are located at the second main compression temperature. The control unit may control the temperatures of the regions in which the first hot wire 225a, the second hot wire 225b, the third hot wire 225c, the fourth hot wire 225d, and the fifth hot wire 225e are located by controlling the flows of coolant in the cooling pipes 226, respectively.

As described above, the bonding apparatus 200 includes the second pressure unit 222, which includes the first temperature control unit 224. Even if heat is transferred from the first pressure unit 121 to the second pressure unit 222 when the first main compression process and the second main compression process are performed simultaneously, the second main compression temperature of the second pressure unit 222 can be maintained at a desired temperature. The first main compression process may include thermally compressing the first electronic device 20 using the first pressure unit 121, and the second main compression process may include thermally compressing the second electronic device 30 using the second pressure unit 222.

According to aspects of the invention, the bonding apparatus 200 may reduce an unwanted change in the first main compression temperature of the first pressure unit 121 or the second main compression temperature of the second pressure unit 222. In addition, the bonding apparatus 200 may prevent or limit the lifting of a first anisotropic conductive film 40, which may contact the first electronic device 20, or a second anisotropic conductive film 50, which may contact the second electronic device 30. Accordingly, the reliability of electrical connection between the first electronic device 20 and the pad area PP of the first display substrate 11 may be improved by the first anisotropic conductive film 40. Also, the reliability of electrical connection between the second electronic device 30 and the pad area PP of the first display substrate 11 may be improved by the second anisotropic conductive film 50.

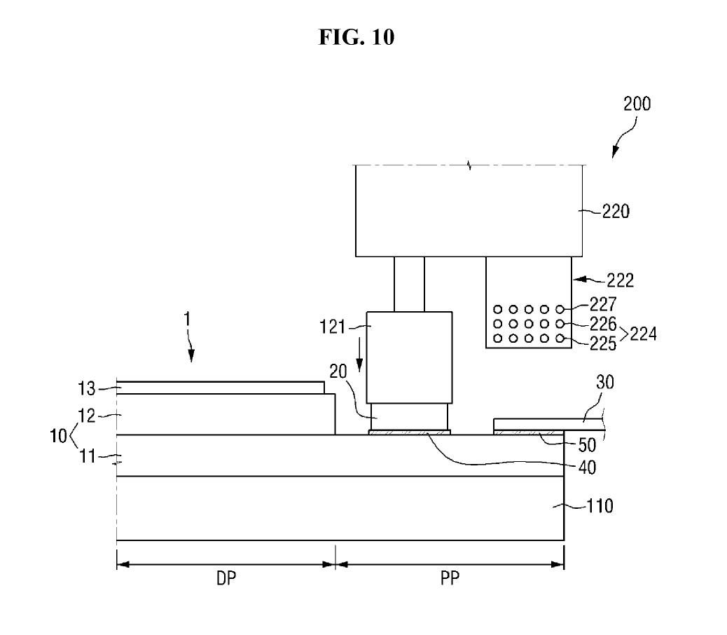

FIGS. 10 through 12 are cross-sectional views illustrating a method of fabricating a display device using the bonding apparatus 200 of FIG. 7.

Referring to FIG. 10, a first anisotropic conductive film 40 may be placed on metal wirings of a pad area PP of a first substrate 11 of a display panel 10, which may be placed on the stage 110. A first electronic device 20 is aligned on the first anisotropic conductive film 40, and the first pressure unit 121 of the bonding head 220 may be moved vertically toward the stage 110 to perform a pre-compression process on the first electronic device 20. The pre-compression process may be performed with a pre-compression pressure and a pre-compression temperature during a pre-compression time. The pre-compression pressure of the first pressure unit 121 and/or heat of the pre-compression temperature of the first pressure unit 121 may be transmitted to the first anisotropic conductive film 40 via the first electronic device 20.

Since the pre-compression process on the first electronic device 20 has been described above with reference to FIG. 2, a repetitive description thereof will be omitted.

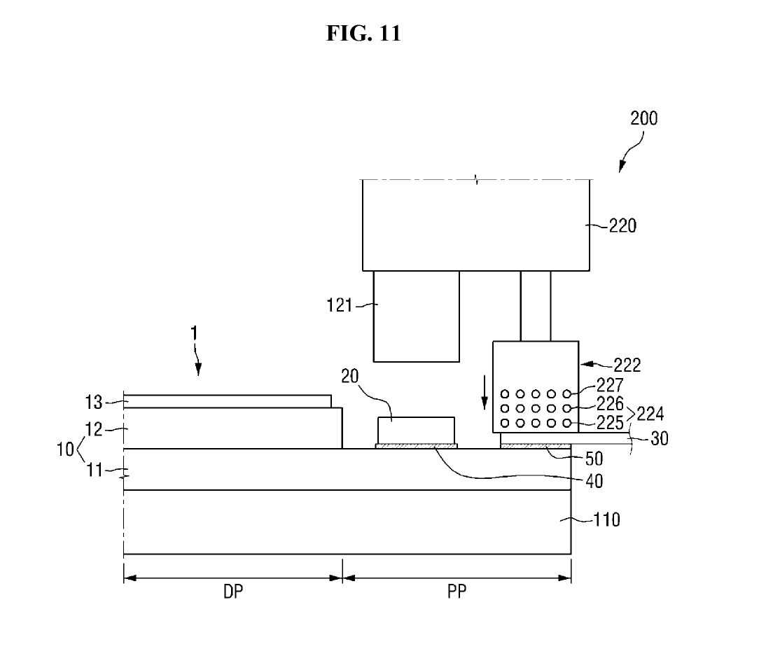

Referring to FIG. 11, a second anisotropic conductive film 50 is placed on the metal wirings of the pad area PP of the first substrate 11 of the display panel 10. A second electronic device 30 is aligned on the second anisotropic conductive film 50, and the second pressure unit 122 of the bonding head 220 may be moved vertically toward the stage 110 to perform a pre-compression process on the second electronic device 30. The pre-compression process may be performed with a pre-compression pressure and a pre-compression temperature during a pre-compression time. The pre-compression pressure of the second pressure unit 222 and/or heat of the pre-compression temperature of the second pressure unit 222 may be transmitted to the second anisotropic conductive film 50 via the second electronic device 30.

The pre-compression process of the second pressure unit 222 may be similar to the pre-compression process of the second pressure unit 122 of FIG. 3. However, the pre-compression temperature of the second pressure unit 222 in the pre-compression process of the second pressure unit 222 can be controlled by the first temperature control unit 224. More specifically, the second pressure unit 222 may have the same pre-compression temperature in all regions thereof because the hot wires 225 provide the same amount or level of heat.

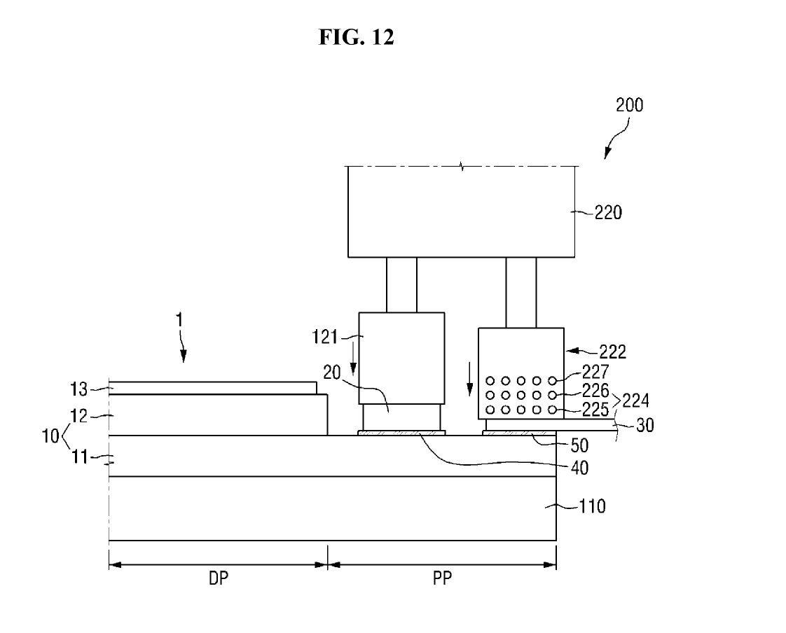

Referring to FIG. 12, the first pressure unit 121 and the second pressure unit 222 of the bonding head 220 may be moved vertically toward the stage 110 to simultaneously perform a first main compression process on the first electronic device 20 against the metal wirings of the pad area PP of the first display substrate 11 and a second main compression process on the second electronic device 30 against the metal wirings of the pad area PP of the first display substrate 11. The first main compression process may be performed with a first main compression pressure and a first main compression temperature of the first pressure unit 121. The second main compression process may be performed with a second main compression pressure and a second main compression temperature of the second pressure unit 222.

The first main compression process of the first pressure unit 121 and the second main compression process of the second pressure unit 222 may be similar to the first main compression process of the first pressure unit 121 and the second main compression process of the second pressure unit 122 in FIG. 4. However, the second main compression temperature of the second pressure unit 222 may be controlled in one or more regions of the second pressure unit 222 by using the first temperature control unit 224 to maintain the second main compression temperature of the second pressure unit 222 even when heat is transferred from the first pressure unit 121 to the second pressure unit 222 in the first main compression process of the first pressure unit 121 and the second main compression process of the second pressure unit 222. Since controlling the second main compression temperature of the second pressure unit 222 in one or more regions of the second pressure unit 222 by using the first temperature control unit 224 has been described above, a repetitive description thereof will be omitted.

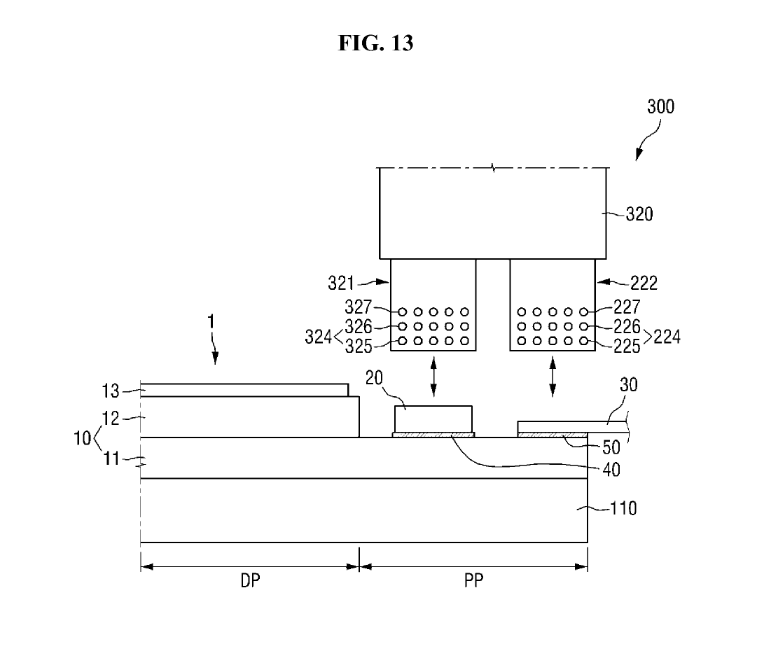

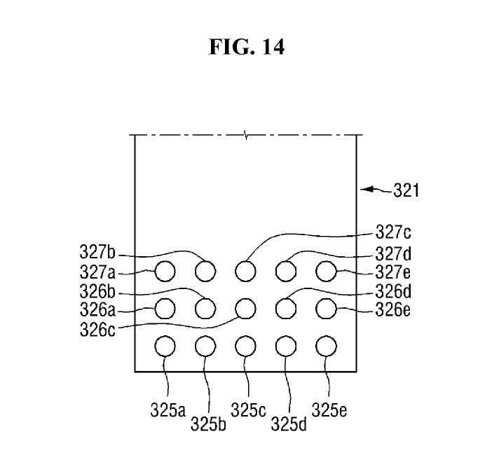

FIG. 13 is a cross-sectional view of a bonding apparatus according to an exemplary embodiment of the present invention. FIG. 14 is an enlarged cross-sectional view of a first pressure unit 321 illustrated in FIG. 13.

Referring to FIG. 13, the bonding apparatus 300 has similar or the same configuration as the bonding apparatus 100 of FIG. 1 except the first pressure unit 321 and a second pressure unit 222, and except omission of the heat dissipation unit 130. Therefore, the first pressure unit 321 and the second pressure unit 222 of the bonding apparatus 300 will be mainly described below.

Referring to FIGS. 13 and 14, the bonding apparatus 300 includes a stage 110 and a bonding head 320.

The bonding head 320 is placed above the stage 110 and operates to have a first electronic device 20 and a second electronic device 30 contact metal wirings of a display panel 10, more specifically, a pad area PP of a first display substrate 11. The contact by the first electronic device 20 and the second electronic device may be made by thermally compressing the first electronic device 20 and the second electronic device 30 onto the pad area PP of the first display unit substrate 11. The bonding head 320 includes the first pressure unit 321 and the second pressure unit 222.

The first pressure unit 321 may be similar to the first pressure unit 121 of FIG. 1. The first pressure unit 321 includes a second temperature control unit 324 and a second temperature sensor 327.

The second temperature control unit 324 includes a plurality of hot wires 325. Heat may be transmitted, to the plurality of hot wires 325, from a heat source (e.g., a heater) and a plurality of cooling pipes 326, through which coolant flows. The second temperature control unit 324 may control the temperature in one or more regions of the first pressure unit 321. The hot wires 325 may include a first hot wire 325a, a second hot wire 325b, a third hot wire 325c, a fourth hot wire 325d, and a fifth hot wire 325e, which may be arranged sequentially in order of largest to smallest distance from the second pressure unit 222. The cooling pipes 326 may cool the hot wires 325 and may include a first cooling pipe 326a, a second cooling pipe 326b, a third cooling pipe 326c, a fourth cooling pipe 326d, and a fifth cooling pipe 326e, which may correspond to the first hot wire 325a, the second hot wire 325b, the third hot wire 325c, the fourth hot wire 325d, and the fifth hot wire 325e, respectively.

The second temperature control unit 324 may provide heat to the first pressure unit 321 through the hot wires 325, such that the first pressure unit 321 can have a pre-compression temperature when performing a pre-compression process on the first electronic device 20 after moving vertically toward the stage 110. The first hot wire 325a, the second hot wire 325b, the third hot wire 325c, the fourth hot wire 325d and the fifth hot wire 325e may equally provide heat of the pre-compression temperature to the first pressure unit 321.

When the temperature of a partial region of the first pressure unit 321, for example, a region in which the third hot wire 325c is located is higher than the pre-compression temperature, the region in which the third hot wire 325c is located is cooled using the third cooling pipe 326c to adjust the temperature of the region in which the third hot wire 325c is located to the pre-compression temperature. The pre-compression temperature may be, for example, approximately 80° C.

In addition, the second temperature control unit 324 may provide heat to the first pressure unit 321 through the hot wires 325 such that the first pressure unit 321 can have a first main compression temperature when performing a first main compression process on the first electronic device 20 after moving vertically toward the stage 110. Of the first hot wire 325a, the second hot wire 325b, the third hot wire 325c, the fourth hot wire 325d, and the fifth hot wire 325e, the first hot wire 325a and the fifth hot wire 325e located in an edge region of the first pressure unit 321 may provide heat of a temperature higher than the first main compression temperature. Therefore, it is possible to prevent or impede the temperature of the edge region of the first pressure unit 321 from becoming lower than the first main compression temperature due to the dissipation of the heat of the edge region to the outside. The first main compression temperature may be, for example, approximately 220° C.

The second temperature sensor 327 includes an equal number of sensor units to the number of the hot wires 325 at positions corresponding to the hot wires 325, respectively. The sensor units 327a, 327b, 327c and 327d respectively sense temperatures of regions of the first pressure unit 321 in which the first hot wire 325a, the second hot wire 325b, the third hot wire 325c, the fourth hot wire 325d and the fifth hot wire 325e are located, and may provide temperature information to a control unit (not illustrated), which may control the overall operation of the bonding apparatus 300. Accordingly, the control unit may maintain the temperatures of the regions of the first pressure unit 321 in which the first hot wire 325a, the second hot wire 325b, the third hot wire 325c, the fourth hot wire 325d and the fifth hot wire 325e are located at the first main compression temperature. The control unit may control the temperatures of the regions in which the first hot wire 325a, the second hot wire 325b, the third hot wire 325c, the fourth hot wire 325d, and the fifth hot wire 325e are located by controlling the flow of coolant in the cooling pipes 326, respectively.

Since the second pressure unit 222 has been described above with reference to FIG. 7, a repetitive description thereof will be omitted.

As described above, the bonding apparatus 300 includes the first pressure unit 321, which includes the second temperature control unit 324, and the second pressure unit 222, which includes a first temperature control unit 224. Therefore, when the first main compression process and a second main compression process are performed simultaneously, the first main compression temperature of the first pressure unit 321 can be maintained at a desired temperature. Further, the second main compression temperature of the second pressure unit 222 can be maintained at a desired temperature even if heat is transferred from the first pressure unit 321 to the second pressure unit 222. The first main compression process includes thermally compressing the first electronic device 20 using the first pressure unit 321, and the second main compression process includes thermally compressing the second electronic device 30 using the second pressure unit 222.

According to aspects of the invention, the bonding apparatus 300 can reduce an unwanted change in the first main compression temperature of the first pressure unit 321 or the second main compression temperature of the second pressure unit 222. In addition, the bonding apparatus 300 can prevent or limit the lifting of a first anisotropic conductive film 40, which contacts the first electronic device 20, or a second anisotropic conductive film 50, which contacts the second electronic device 30. Accordingly, the reliability of electrical connection between the first electronic device 20 and the pad area PP of the first display substrate 11 may be improved by the first anisotropic conductive film 40. Further, the reliability of electrical connection between the second electronic device 30 and the pad area PP of the first display substrate 11 may be improved by the second anisotropic conductive film 50.

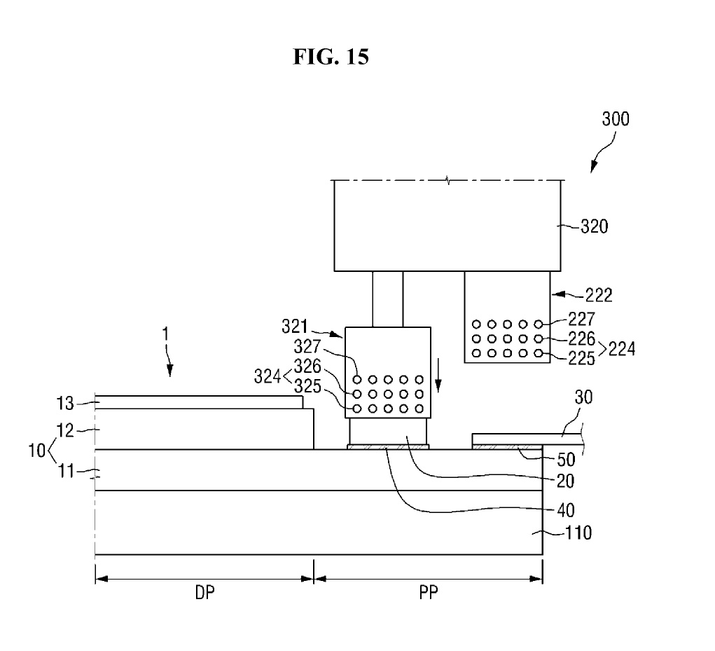

FIGS. 15 through 17 are cross-sectional views illustrating a method of fabricating a display device using the bonding apparatus 300 of FIG. 13.

Referring to FIG. 15, a first anisotropic conductive film 40 is placed on metal wirings of a pad area PP of a first substrate 11 of a display panel 10 placed on the stage 110. A first electronic device 20 is aligned on the first anisotropic conductive film 40, and the first pressure unit 321 of the bonding head 320 may be moved vertically toward the stage 110 to perform a pre-compression process on the first electronic device 20. The pre-compression process may be performed with a pre-compression pressure and a pre-compression temperature during a pre-compression time. Here, the pre-compression pressure of the first pressure unit 321 and/or heat of the pre-compression temperature of the first pressure unit 321 may be transmitted to the first anisotropic conductive film 40 via the first electronic device 20.

The pre-compression process of the first pressure unit 321 is similar to the pre-compression process of the first pressure unit 121 of FIG. 2. However, the pre-compression temperature of the first pressure unit 321 in the pre-compression process of the first pressure unit 321 can be controlled by the second temperature control unit 324. More specifically, the first pressure unit 321 may have the same pre-compression temperature in some or all regions thereof because the hot wires 325 provide the same level or amount of heat.

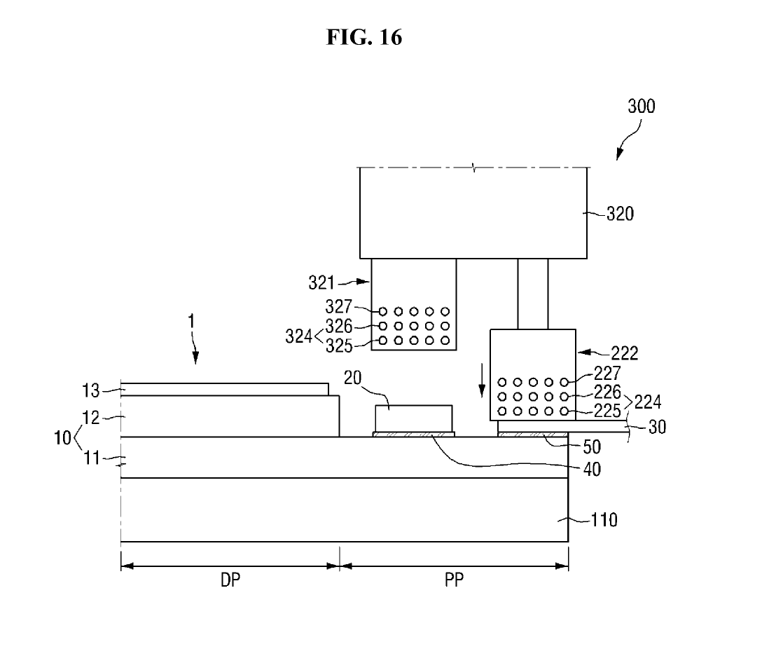

Referring to FIG. 16, a second anisotropic conductive film 50 may be placed on the metal wirings of the pad area PP of the first substrate 11 of the display panel 10. A second electronic device 30 is aligned on the second anisotropic conductive film 50, and the second pressure unit 122 of the bonding head 320 may be moved vertically toward the stage 110 to perform a pre-compression process on the second electronic device 30. The pre-compression process may be performed with a pre-compression pressure and a pre-compression temperature during a pre-compression time. Here, the pre-compression pressure of the second pressure unit 222 and/or heat of the pre-compression temperature of the second pressure unit 222 may be transmitted to the second anisotropic conductive film 50 via the second electronic device 30.

The pre-compression process of the second pressure unit 222 may be similar to the pre-compression process of the second pressure unit 122 of FIG. 3. However, the pre-compression temperature of the second pressure unit 222 in the pre-compression process of the second pressure unit 222 can be controlled by the first temperature control unit 224. More specifically, the second pressure unit 222 may have the same pre-compression temperature in all regions thereof because a plurality of hot wires 225 may provide the same level or amount of heat.

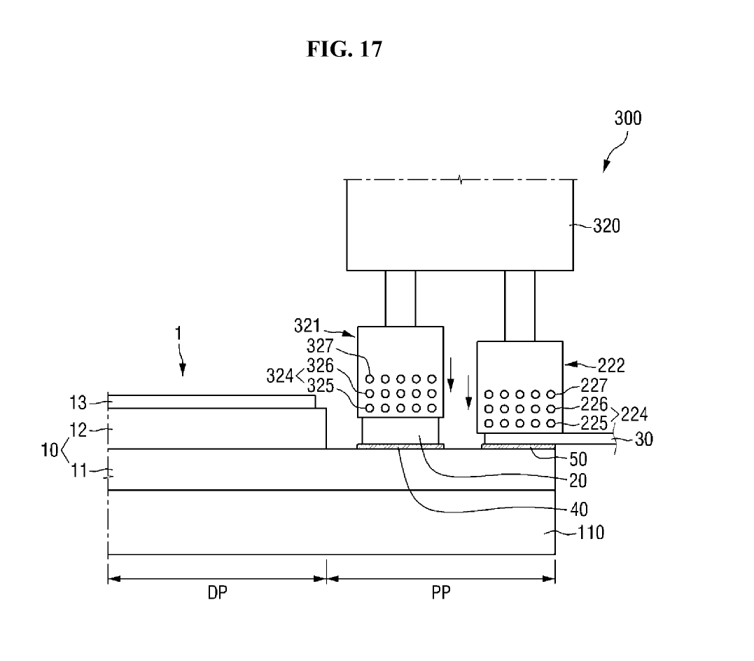

Referring to FIG. 17, the first pressure unit 321 and the second pressure unit 222 of the bonding head 320 may be moved vertically toward the stage 110 to simultaneously perform a first main compression process and a second main compression process. The first main compression process may be performed on the first electronic device 20 against the metal wirings of the pad area PP of the first display substrate 11 with a first main compression pressure and a first main compression temperature of the first pressure unit 321. The second main compression process may be performed on the second electronic device 30 against the metal wirings of the pad area PP of the first display substrate 11 with a second main compression pressure and a second main compression temperature of the second pressure unit 222.

The first main compression process of the first pressure unit 321 and the second main compression process of the second pressure unit 222 may be similar to the first main compression process of the first pressure unit 121 and the second main compression process of the second pressure unit 122 in FIG. 4. However, the first main compression temperature of the first pressure unit 321 may be controlled in one or more regions of the first pressure unit 321 by using the second temperature control unit 324 to prevent or impede the temperature of the edge region of the first pressure unit 321 from becoming lower than the first main compression temperature, due, at least in part, to the dissipation of the heat of the edge region to the outside in the first main compression process of the first pressure unit 321 and the second main compression process of the second pressure unit 222. In addition, the temperature of the second pressure unit 222 may be controlled in one or more regions of the second pressure unit 222 to maintain the temperature of the second pressure unit 222 at a constant temperature by using the first temperature control unit 224 even when heat is transferred from the first pressure unit 321 to the second pressure unit 222. Since controlling the first main compression temperature of the first pressure unit 321 in one or more regions of the first pressure unit 321 by using the second temperature control unit 324, and controlling the second main compression temperature of the second pressure unit 222 in one or more regions of the second pressure unit 222 by using the first temperature control unit 224 have been described above, a repetitive description thereof will be omitted.

Although various compression processes were described as being performed at the same time, aspects of the invention are not limited thereto, such that two or more processes may be performed within similar time frame or within a reference duration of the other.

Exemplary embodiments of the present invention may provide at least one of the following advantages.

A bonding apparatus according to exemplary embodiments of the present invention includes a heat dissipation unit between a first pressure unit and a second pressure unit. Accordingly, the bonding apparatus can prevent or reduce heat transfer between the first pressure unit and the second pressure unit when a first main compression process and a second main compression process are performed simultaneously. The first main compression process includes thermally compressing a first electronic device using the first pressure unit. The second main compression process includes thermally compressing a second electronic device using the second pressure unit.

The bonding apparatus according to exemplary embodiments of the present invention can reduce an unwanted change in a first main compression temperature of the first pressure unit or a second main compression temperature of the second pressure unit. Accordingly, the lifting or movement of a first anisotropic conductive film, which may contact the first electronic device, or a second anisotropic conductive film, which contacts the second electronic device may be prevented against or limited.

However, effects of the present invention are not restricted to the one set forth herein. The above and other effects of the present invention will become more apparent to one of daily skill in the art to which the present invention pertains by referencing the claims.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A method of fabricating a display device, the method comprising:
placing a first anisotropic conductive film on a display panel;
aligning a first electronic device on the first anisotropic conductive film;
performing a pre-compression process on the first electronic device using a first pressure unit;
placing a second anisotropic conductive film on the display panel;
aligning a second electronic device on the second anisotropic conductive film;
performing a pre-compression process on the second electronic device using a second pressure unit separated from the first pressure unit; and
simultaneously performing a first main compression process on the first electronic device at a first temperature using the first pressure unit, and a second main compression process on the second electronic device at a second temperature different from the first temperature using the second pressure unit,
wherein the second main compression process is performed by maintaining the second temperature using a first temperature control unit.

2. The method of claim 1, wherein the first temperature control unit is a heat dissipation unit disposed between the first pressure unit and the second pressure unit, and comprises a heat dissipation material.

3. The method of claim 2, wherein the first main compression process and the second main compression process are performed when the heat dissipation unit is disposed on the display panel and between the first electronic device and the second electronic device.

4. The method of claim 2, wherein the heat dissipation unit comprises at least any one of a silica-based material, an aerogel-based material, a polyurethane-based material, a polyisocyanurate-based material, a phenol-based material, a urea-based material, a polystyrene-based material, a fiberglass-based material, an icynene-based material, a cotton-based material, a wool-based material, a cellulose-based material, a polyethylene-based material, a vermiculite-based material, and glass.

5. The method of claim 2, wherein the heat dissipation unit comprises a wax-based material or an inorganic material.

6. The method of claim 1, wherein the first temperature control unit is installed in the second pressure unit and comprises:
a plurality of hot wires to provide heat to the second pressure unit; and
a plurality of cooling pipes disposed at positions corresponding to the hot wires, and configured to cool heat of the hot wires and maintain the second temperature at the second pressure unit.

7. The method of claim 6, wherein the hot wires comprise a first hot wire, a second hot wire, a third hot wire, a fourth hot wire and a fifth hot wire disposed sequentially in order of distance from the first pressure unit, wherein the first hot wire, the second hot wire, the third hot wire, the fourth hot wire and the fifth hot wire are configured to provide heat of a temperature lower than the second temperature to the second pressure unit, and the provided heat is increased from the first hot wire toward the fifth hot wire.

8. The method of claim 6, wherein the second pressure unit further comprises a first temperature sensor having a plurality of sensor units installed at positions corresponding to the hot wires, the plurality of sensor units configured to sense temperatures of regions in which the hot wires are located.

9. The method of claim 1, wherein the first pressure unit comprises the first temperature control unit and a second temperature control unit configured to maintain the first temperature when the first main compression process is performed.

10. The method of claim 9, wherein the second temperature control unit comprises:
a plurality of hot wires configured to provide heat to the first pressure unit; and
a plurality of cooling pipes located at positions corresponding to the hot wires, and configured to cool heat of the hot wires and maintain the first temperature at the first pressure unit.

11. The method of claim 10, wherein the hot wires comprise a first hot wire, a second hot wire, a third hot wire, a fourth hot wire and a fifth hot wire located sequentially in order of distance from the second pressure unit, wherein the first hot wire and the fifth hot wire provide heat of a temperature higher than the first temperature to the first pressure unit.

12. The method of claim 10, wherein the first pressure unit further comprises a second temperature sensor having a plurality of sensor units installed at positions corresponding to the hot wires, the sensor units configured to sense temperature of one or more regions in which the hot wires are located.

13. The method of claim 1, wherein the first electronic device is a driver chip, and the second electronic device is a flexible circuit board.

14. A method of fabricating a display device, the method comprising:
disposing a first anisotropic conductive film on a display panel;
aligning a first electronic device on the first anisotropic conductive film;
disposing a second anisotropic conductive film on the display panel;
aligning a second electronic device on the second anisotropic conductive film;
performing a first thermal compression on the first electronic device at a first temperature using a first pressure unit; and
performing a second thermal compression on the second electronic device at a second temperature different from the first temperature using a second pressure unit,
wherein the first thermal compression process and the second thermal compression process are simultaneously performed, and
wherein the second thermal compression process is performed by maintaining the second temperature using a first temperature control unit.

15. The method of claim 14, wherein the first temperature control unit is a heat dissipation unit disposed between the first pressure unit and the second pressure unit, and comprises a heat dissipation material.

16. The method of claim 14, wherein the first temperature control unit is installed in the second pressure unit and comprises:
a plurality of hot wires to provide heat to the second pressure unit; and
a plurality of cooling pipes disposed at positions corresponding to the hot wires, and configured to cool heat of the hot wires and maintain the second temperature at the second pressure unit.

17. The method of claim 14, wherein the first pressure unit comprises the first temperature control unit and a second temperature control unit configured to maintain the first temperature when the first thermal compression process is performed.

18. The method of claim 14, wherein the first electronic device is a driver chip, and the second electronic device is a flexible circuit board.
